(19) United States
(12) Patent Application Publication
(10) Pub. No.: US 2024/0429898 A1
(43) Pub. Date: Dec. 26, 2024

(54) Phase-Invariant Signal Attenuator

(71) Applicant: Apple Inc., Cupertino, CA (US)

(72) Inventors: Milad Darvishi, San Diego, CA (US); Seyedmohammadreza Razavian, San Diego, CA (US)

(21) Appl. No.: 18/339,159

(22) Filed: Jun. 21, 2023

(51) Int. Cl. H03H 11/24; H01Q 3/36

(52) U.S. Cl. CPC H03H 11/24; H01Q 3/36; H03F 3/245; H03F 2200/451; H04B 1/16

(57) ABSTRACT

An electronic device may have wireless circuitry that includes a differential signal path having first and second signal lines. A pi attenuator may be disposed on the differential signal path. The pi attenuator may include a first series resistor on the first signal line, a second series resistor on the second signal line, and parallel resistors coupled between the first and second signal lines on opposing sides of the series resistors. A first capacitor may couple an input terminal of the first series resistor to an output terminal of the second series resistor and a second capacitor may couple an output terminal of the first series resistor to an input terminal of the second series resistor. The capacitors may serve to minimize phase variation as a function of attenuation level in attenuated signals output by the pi attenuator.

### FIELD

This disclosure relates generally to electronic devices and, more particularly, to electronic devices with wireless communications circuitry.

### BACKGROUND

Electronic devices are often provided with wireless communications capabilities. An electronic device with wireless communications capabilities has wireless communications circuitry with signal paths that convey radio-frequency signals.

It can be challenging to ensure that the radio-frequency signals conveyed along the signal paths are provided at satisfactory voltage levels and with consistent phases.

### SUMMARY

An electronic device may include wireless circuitry for performing wireless communications. The wireless circuitry may include a transceiver, as phased antenna array, and differential signal paths coupled to the phased antenna array. Phase and magnitude controllers may control beam forming by the phased antenna array. The phase and magnitude controllers may include signal attenuators. The signal attenuators may be programmable to provide different attenuation levels to radio-frequency signals conveyed over the phased antenna array. More generally, the signal attenuators may be disposed on any desired differential signal paths in the device.

Each signal attenuator may be a resistive pi attenuator having a pi network of resistors disposed on the corresponding differential signal path. The resistors may include a first series resistor disposed on a first signal line of the differential signal path, a second series resistor disposed on a second signal line of the differential signal path, and parallel resistors coupled between the first and second signal lines on opposing sides of the series resistors. The signal attenuator may include a first capacitor that couples a first (input) terminal of the first series resistor to a second (output) terminal of the second series resistor. The signal attenuator may include a second capacitor that couples a second (output) terminal of the first series resistor to a first (input) terminal of the second series resistor. The capacitors may have capacitances equal to a parasitic capacitance of switching circuitry in one or more of the resistors of the signal attenuator.

The capacitors may serve to cancel out undesirable feed-forward current paths in the resistor(s), which may configure the signal attenuator to output attenuated signals having minimal phase variation across different attenuation levels. In implementations where the signal attenuators are used to attenuate radio-frequency signals for the phased antenna array, the signal attenuators may perform gain-tapering that provides spatial filtering for the phased antenna array. The spatial filtering may help to prevent undesirable jammer signals from interfering with a signal of interest even as the signal attenuators are adjusted between different attenuation levels.

An aspect of the disclosure provides an electronic device. The electronic device may include a differential signal path configured to convey a radio-frequency signal, the differential signal path having a first signal line and a second signal line. The electronic device may include a first resistor coupled between a first node on the first signal line and a second node on the second signal line. The electronic device may include a second resistor coupled between a third node on the first signal line and a fourth node on the second signal line. The electronic device may include a third resistor disposed on the first signal line between the first node and the second node. The electronic device may include a first capacitor coupled between the first node and the fourth node. The electronic device may include a second capacitor coupled between the second node and the third node.

An aspect of the disclosure provides wireless circuitry. The wireless circuitry may include a phased antenna array having an antenna. The wireless circuitry may include a differential signal path coupled to the antenna and having a first signal line and a second signal line. The wireless circuitry may include a pi network disposed on the differential signal path. The pi network may include a first resistor disposed on the first signal line, the first resistor having a resistance that is adjustable to configure the pi network to attenuate, by different attenuation levels, a radio-frequency signal conveyed using the antenna. The wireless circuitry may include a first capacitor that couples a first terminal of the first resistor to the second signal line. The wireless circuitry may include a second capacitor that couples a second terminal of the first resistor to the second signal line.

An aspect of the disclosure provides radio-frequency circuitry. The radio-frequency circuitry may include a first signal line coupled between a first input terminal and a first output terminal. The radio-frequency circuitry may include a second signal line coupled between a second input terminal and a second output terminal of the signal attenuator, wherein the first signal line and the second signal line form a differential pair of signal lines. The radio-frequency circuitry may include a first resistor disposed on the first signal line between the first input terminal and the first output terminal. The radio-frequency circuitry may include a second resistor disposed on the second signal line between the second input terminal and the second output terminal. The radio-frequency circuitry may include a first capacitor that couples the first input terminal to the second output terminal. The radio-frequency circuitry may include a second capacitor that couples the second input terminal to the first output terminal.

### BRIEF DESCRIPTION OF THE DRAWINGS

FIG. 1 is a schematic diagram of an illustrative electronic device having wireless circuitry in accordance with some embodiments.

FIG. 2 is a diagram of an illustrative phased antenna array that may be adjusted to form beams of signals oriented in different directions in accordance with some embodiments.

FIG. 3 is a circuit diagram showing how an illustrative phased antenna array may be provided with programmable signal attenuators in accordance with some embodiments.

FIG. 4 is a circuit diagram showing how an illustrative programmable signal attenuator may be disposed on a differential signal path between first and second circuit blocks in accordance with some embodiments.

FIG. 5 is a circuit diagram of an illustrative programmable signal attenuator formed from a pi network of adjustable resistors with cross-coupled capacitors between differential signal lines in accordance with some embodiments.

FIG. 6 is a circuit diagram of an illustrative adjustable resistor having multiple banks of switches for adjusting the resistance of the adjustable resistor in accordance with some embodiments.

FIGS. 7-9 are equivalent circuit diagrams showing how illustrative cross-coupled capacitors may effectively cancel out parasitic capacitances of the adjustable resistors in a pi network used to form a programmable signal attenuator in accordance with some embodiments.

FIG. 10 is a plot showing how illustrative cross-coupled capacitors of the type shown in FIG. 5 may minimize phase variation across attenuation levels of a programmable signal attenuator in accordance with some embodiments.

### DETAILED DESCRIPTION

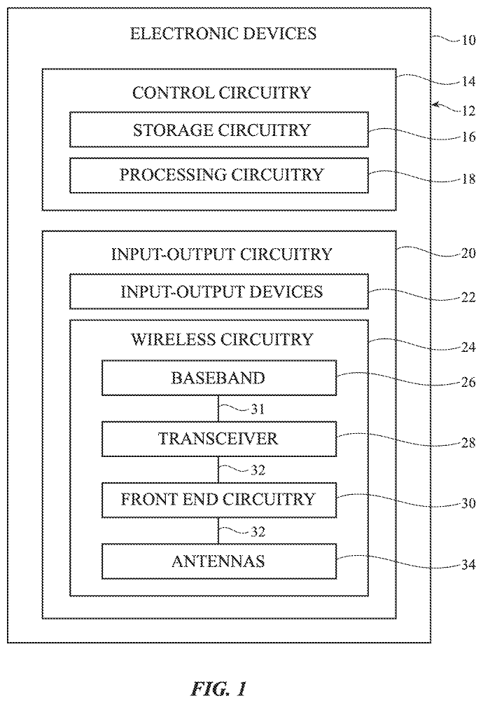

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head (e.g., a head-mounted device or head-mounted display), or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, part or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24 or radio-frequency circuitry 24) may include baseband circuitry such as baseband circuitry 26 (e.g., one or more baseband processors and/or other circuitry that operates at baseband), radio-frequency (RF) transceiver circuitry such as transceiver 28, radio-frequency front end circuitry such as front end circuitry 30, and one or more antennas 34. If desired, wireless circuitry 24 may include multiple antennas 34 that are arranged into a phased antenna array (sometimes referred to as a phased array antenna) that conveys radio-frequency signals within a corresponding signal beam that can be steered in different directions. Baseband circuitry 26 may be coupled to transceiver 28 over one or more baseband signal paths 31. Baseband circuitry 26 may include, for example, modulators (encoders) and demodulators (decoders) that operate on baseband signals. Transceiver 28 may be coupled to antennas 34 over one or more radio-frequency transmission line paths 32 (sometimes referred to herein as radio-frequency signal paths 32). Front end circuitry 30 may be disposed on radio-frequency transmission line path(s) 32 between transceiver 28 and antennas 34.

In the example of FIG. 1, wireless circuitry 24 is illustrated as including only a single transceiver 28 and a single radio-frequency transmission line path 32 for the sake of clarity. In general, wireless circuitry 24 may include any desired number of transceivers 28, any desired number of radio-frequency transmission line paths 32, and any desired number of antennas 34. Each transceiver 28 may be coupled to one or more antennas 34 over respective radio-frequency transmission line paths 32. Each radio-frequency transmission line path 32 may have respective front end circuitry 30 disposed thereon. If desired, front end circuitry 30 may be shared by multiple radio-frequency transmission line paths 32.

Radio-frequency transmission line path(s) 32 may be coupled to antenna feeds on one or more antennas 34. Each antenna feed may, for example, include a positive antenna feed terminal and a ground antenna feed terminal. Each radio-frequency transmission line path 32 may have a positive transmission line signal path (signal conductor) that is coupled to one or more positive antenna feed terminals and may have a ground transmission line signal path (ground conductor) that is coupled to the ground antenna feed terminal. This example is merely illustrative and, in general, antennas 34 may be fed using any desired antenna feeding scheme.

Each radio-frequency transmission line path 32 may include one or more radio-frequency transmission lines that are used to route radio-frequency signals within device 10. Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Radio-frequency transmission line paths 32 may also include radio-frequency connectors that couple multiple transmission lines together. Transmission lines in device 10 such as transmission lines in a radio-frequency transmission line path 32 may be integrated into rigid and/or flexible printed circuit boards. In some implementations, radio-frequency transmission line paths such as radio-frequency transmission line path 32 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

In performing wireless transmission, baseband circuitry 26 may provide baseband signals to transceiver 28 over baseband signal path(s) 31. Transceiver 28 may sometimes also be referred to herein as radio 28. Transceiver 28 (e.g., one or more transmitters in transceiver 28) may include circuitry for converting the baseband signals received from baseband circuitry 26 into corresponding radio-frequency signals. For example, transceiver 28 may include mixer circuitry that up-converts the baseband signals to radio frequencies prior to transmission over antennas 34. Transceiver 28 may also include digital to analog converter (DAC) and/or analog to digital converter (ADC) circuitry that converts signals between digital and analog domains. Transceiver 28 may transmit the radio-frequency signals over antennas 34 via radio-frequency transmission line path 32 and front end circuitry 30. Antennas 34 may transmit the radio-frequency signals to external wireless equipment by radiating the radio-frequency signals into free space.

In performing wireless reception, antennas 34 may receive radio-frequency signals from the external wireless equipment. The received radio-frequency signals may be conveyed to transceiver 28 via radio-frequency transmission line path 32 and front end circuitry 30. Transceiver 28 may include circuitry for converting the received radio-frequency signals into corresponding baseband signals. For example, transceiver 28 may include one or more receivers having mixer circuitry that down-converts the received radio-frequency signals to baseband frequencies prior to conveying the baseband signals to baseband circuitry 26.

Front end circuitry 30 may include radio-frequency front end components that operate on radio-frequency signals conveyed over radio-frequency transmission line path 32. If desired, the radio-frequency front end components may be formed within one or more radio-frequency front end modules (FEMs). Each FEM may include a common substrate such as a printed circuit board substrate for each of the radio-frequency front end components in the FEM. The radio-frequency front end components in front end circuitry 30 may include switching circuitry (e.g., one or more radio-frequency switches), radio-frequency filter circuitry (e.g., low pass filters, high pass filters, notch filters, band pass filters, multiplexing circuitry, duplexer circuitry, diplexer circuitry, triplexer circuitry, etc.), impedance matching circuitry (e.g., circuitry that helps to match the impedance of antennas 34 to the impedance of radio-frequency transmission line path 32), antenna tuning circuitry (e.g., networks of capacitors, resistors, inductors, and/or switches that adjust the frequency response of antennas 34), radio-frequency amplifier circuitry (e.g., power amplifier circuitry and/or low-noise amplifier circuitry), radio-frequency coupler circuitry, charge pump circuitry, power management circuitry, digital control and interface circuitry, and/or any other desired circuitry that operates on the radio-frequency signals transmitted and/or received by antennas 34.

While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, baseband circuitry 26 and/or portions of transceiver 28 (e.g., a host processor on transceiver 28) may form a part of control circuitry 14.

Wireless circuitry 24 may transmit and/or receive wireless signals within corresponding frequency bands of the electromagnetic spectrum (sometimes referred to herein as communications bands or simply as “bands”). The frequency bands handled by wireless circuitry 24 may include wireless local area network (WLAN) frequency bands (e.g., Wi-Fi® (IEEE 802.11) or other WLAN communications bands) such as a 2.4 GHZ WLAN band (e.g., from 2400 to 2480 MHz), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, near-field communications (NFC) frequency bands (e.g., at 13.56 MHZ), satellite navigation frequency bands (e.g., a GPS band from 1565 to 1610 MHZ, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

Antennas 34 may be formed using any desired antenna structures. For example, antennas 34 may include antennas with resonating elements that are formed from loop antenna structures, patch antenna structures, inverted-F antenna structures, slot antenna structures, planar inverted-F antenna structures, helical antenna structures, monopole antennas, dipoles, hybrids of these designs, etc. Parasitic elements may be included in antennas 34 to adjust antenna performance.

Filter circuitry, switching circuitry, impedance matching circuitry, and other circuitry may be interposed within radio-frequency transmission line path 32, may be incorporated into front end circuitry 30, and/or may be incorporated into antennas 34 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antennas 34 over time.

In general, transceiver 28 may cover (handle) any suitable communications (frequency) bands of interest. The transceiver may convey radio-frequency signals using antennas 34 (e.g., antennas 34 may convey the radio-frequency signals for the transceiver circuitry). The term “convey radio-frequency signals” as used herein means the transmission and/or reception of the radio-frequency signals (e.g., for performing unidirectional and/or bidirectional wireless communications with external wireless communications equipment). Antennas 34 may transmit the radio-frequency signals by radiating the radio-frequency signals into free space (or to free space through intervening device structures such as a dielectric cover layer). Antennas 34 may additionally or alternatively receive the radio-frequency signals from free space (e.g., through intervening devices structures such as a dielectric cover layer). The transmission and reception of radio-frequency signals by antennas 34 each involve the excitation or resonance of antenna currents on an antenna resonating element in the antenna by the radio-frequency signals within the frequency band(s) of operation of the antennas.

In example where multiple antennas 34 are arranged in a phased antenna array, each antenna 34 may form a respective antenna element of the phased antenna array. Conveying radio-frequency signals using the phased antenna array may allow for greater peak signal gain relative to scenarios where individual antennas 34 are used to convey radio-frequency signals. In satellite navigation system links, cellular telephone links, and other long-range links, radio-frequency signals are typically used to convey data over thousands of feet or miles. In Wi-Fi® and Bluetooth® links at 2.4 and 5 GHz and other short-range wireless links, radio-frequency signals are typically used to convey data over tens or hundreds of feet. In scenarios where millimeter or centimeter wave frequencies are used to convey radio-frequency signals, a phased antenna array may convey radio-frequency signals over short distances that travel over a line-of-sight path. To enhance signal reception for millimeter and centimeter wave communications, the phased antenna array may convey radio-frequency signals using beam steering techniques (e.g., schemes in which antenna signal phase and/or magnitude for each antenna in an array are adjusted to perform beam steering).

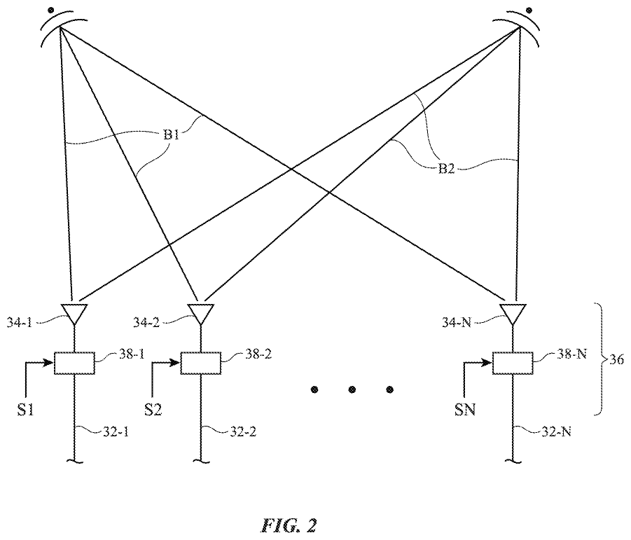

FIG. 2 shows how antennas 34 may be formed in a corresponding phased antenna array 36. As shown in FIG. 2, phased antenna array 36 (sometimes referred to herein as array 36, antenna array 36, or array 36 of antennas 34) may be coupled to radio-frequency transmission line paths 32. For example, a first antenna 34-1 in phased antenna array 36 may be coupled to a first radio-frequency transmission line path 32-1, a second antenna 34-2 in phased antenna array 36 may be coupled to a second radio-frequency transmission line path 32-2, an Nth antenna 34-N in phased antenna array 36 may be coupled to an Nth radio-frequency transmission line path 32-N, etc. While antennas 34 are described herein as forming a phased antenna array, the antennas 34 in phased antenna array 36 may sometimes also be referred to as collectively forming a single phased array antenna (e.g., where antennas 34 form antenna elements of the phased array antenna).

Antennas 34 in phased antenna array 36 may be arranged in any desired number of rows and columns or in any other desired pattern (e.g., the antennas need not be arranged in a grid pattern having rows and columns). Each antenna 34 may be separated from one or more adjacent antennas 34 in phased antenna array 36 by a predetermined distance such as approximately half an effective wavelength of operation of the array. During signal transmission operations, radio-frequency transmission line paths 32 may be used to supply signals (e.g., radio-frequency signals such as millimeter wave and/or centimeter wave signals) from transceiver circuitry to phased antenna array 36 for wireless transmission. During signal reception operations, radio-frequency transmission line paths 32 may be used to supply signals received at phased antenna array 36 (e.g., from external wireless equipment or transmitted signals that have been reflected off of external objects) to transceiver circuitry.

The use of multiple antennas 34 in phased antenna array 36 allows beam forming/steering arrangements to be implemented by controlling the relative phases and magnitudes (amplitudes) of the radio-frequency signals conveyed by the antennas. In the example of FIG. 2, antennas 34 each have a corresponding radio-frequency phase and magnitude controller 38 (e.g., a first phase and magnitude controller 38-1 disposed on radio-frequency transmission line path 32-1 may control phase and magnitude for radio-frequency signals handled by antenna 34-1, a second phase and magnitude controller 38-2 disposed on radio-frequency transmission line path 32-2 may control phase and magnitude for radio-frequency signals handled by antenna 34-2, an Nth phase and magnitude controller 38-N disposed on radio-frequency transmission line path 32-N may control phase and magnitude for radio-frequency signals handled by antenna 34-N, etc.).

Phase and magnitude controllers 38 may each include circuitry for adjusting the phase of the radio-frequency signals on radio-frequency transmission line paths 32 (e.g., phase shifter circuits) and/or circuitry for adjusting the magnitude of the radio-frequency signals on radio-frequency transmission line paths 32 (e.g., power amplifier and/or low noise amplifier circuits). Phase and magnitude controllers 38 may sometimes be referred to collectively herein as beam steering circuitry or beam forming circuitry (e.g., beam steering/forming circuitry that steers/forms the beam of radio-frequency signals transmitted and/or received by phased antenna array 36).

Phase and magnitude controllers 38 may adjust the relative phases and/or magnitudes of the transmitted signals that are provided to each of the antennas in phased antenna array 36 and may adjust the relative phases and/or magnitudes of the received signals that are received by phased antenna array 36. Phase and magnitude controllers 38 may, if desired, include phase detection circuitry for detecting the phases of the received signals that are received by phased antenna array 36. The term “beam” or “signal beam” may be used herein to collectively refer to wireless signals that are transmitted and/or received by phased antenna array 36 in a particular direction. Each beam may exhibit a peak gain that is oriented in a respective beam pointing direction at a corresponding beam pointing angle (e.g., based on constructive and destructive interference from the combination of signals from each antenna in the phased antenna array). Different sets of phase and magnitude settings for phase and magnitude controllers 38 may configure phased antenna array 36 to form different beams in different beam pointing directions.

If, for example, phase and magnitude controllers 38 are adjusted to produce a first set of phases and/or magnitudes, the signals will form a beam as shown by beam B1 of FIG. 2 that is oriented in the direction of point A. If, however, phase and magnitude controllers 38 are adjusted to produce a second set of phases and/or magnitudes, the signals will form a beam as shown by beam B2 that is oriented in the direction of point B. Each phase and magnitude controller 38 may be controlled to produce a desired phase and/or magnitude based on a corresponding control signal S received from control circuitry 14 of FIG. 1 (e.g., the phase and/or magnitude provided by phase and magnitude controller 38-1 may be controlled using control signal S1, the phase and/or magnitude provided by phase and magnitude controller 38-2 may be controlled using control signal S2, the phase and/or magnitude provided by phase and magnitude controller 38-N may be controlled using control signal SN, etc.). If desired, the control circuitry may actively adjust control signals S in real time to steer (form) the beam in different desired directions over time. Phase and magnitude controllers 38 may provide information identifying the phase of received signals to control circuitry 14 if desired.

When performing wireless communications using radio-frequency signals at relatively high frequencies such as millimeter and centimeter wave frequencies, radio-frequency signals are conveyed over a line-of-sight path between phased antenna array 36 and external communications equipment. If the external equipment is located at point A of FIG. 2, phase and magnitude controllers 38 may be adjusted to steer the signal beam towards point A (e.g., to steer the pointing direction of the signal beam towards point A). Phased antenna array 36 may transmit and receive radio-frequency signals in the direction of point A. Similarly, if the external equipment is located at point B, phase and magnitude controllers 38 may be adjusted to steer the signal beam towards point B (e.g., to steer the pointing direction of the signal beam towards point B). Phased antenna array 36 may transmit and receive radio-frequency signals in the direction of point B.

In the example of FIG. 2, beam steering is shown as being performed over a single degree of freedom for the sake of simplicity (e.g., towards the left and right on the page of FIG. 2). However, in practice, the beam may be steered over two or more degrees of freedom (e.g., in three dimensions, into and out of the page and to the left and right on the page of FIG. 2). Phased antenna array 36 may have a corresponding field of view over which beam steering can be performed (e.g., in a hemisphere or a segment of a hemisphere over the phased antenna array).

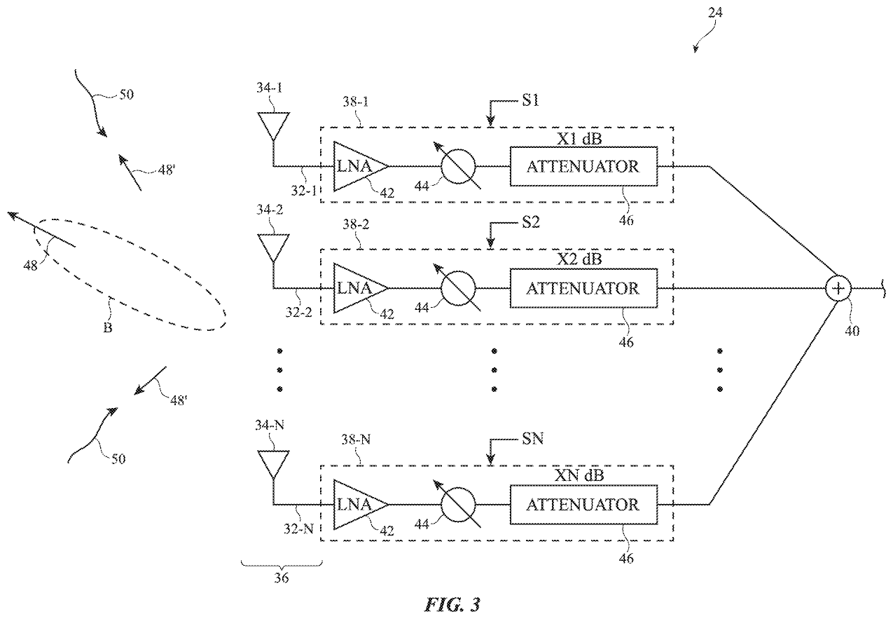

If desired, phase and magnitude controllers 38 may include signal attenuators. FIG. 3 is a circuit diagram showing how the phase and magnitude controllers 38 of phased antenna array 36 may include signal attenuators. As shown in FIG. 3, each phase and magnitude controller 38 may include an amplifier such as low noise amplifier (LNA) 42, a phase shifter such as phase shifter 44, and a signal attenuator such as signal attenuator 46 disposed on the corresponding radio-frequency transmission line path 32.

LNA 42, phase shifter 44, and signal attenuator 46 may, for example, form part of the receive chain of the corresponding antenna 34. If desired, signal attenuator 46 may be coupled between phase shifter 44 and LNA 42 or may be coupled between LNA 42 and antenna 34. Additionally or alternatively, phase and magnitude controllers 48 may include power amplifiers (not shown) for use in transmitting signals using phased antenna array 36 (e.g., attenuators 46 may equivalently be disposed on a transmit chain of the corresponding antenna 34, may be shared by both a receive chain and a transmit chain of a corresponding antenna 34, etc.).

During signal reception, radio-frequency signals may be incident upon phased antenna array 36. Each signal attenuator 46 and LNA 42 may collectively control the magnitude of the signals received by the corresponding antenna 34, whereas each phase shifter 44 controls the phase of the signals received by the corresponding antenna 34. For example, each LNA 42 may be controlled to provide a respective gain to the signals received by the corresponding antenna 34. Each phase shifter 44 may be controlled to provide a respective phase shift to the signals received by the corresponding antenna 34.

Signal attenuators 46 may be programmable (e.g., adjustable or tunable) signal attenuators. As such, each signal attenuator 46 may be controlled to provide a respective signal attenuation level X to the signal received by the corresponding antenna 34. For example, the signal attenuator 46 in phase and magnitude controller 38-1 may apply an attenuation level of X1 dB to the signal received by antenna 34-1, the signal attenuator 46 in phase and magnitude controller 38-2 may apply an attenuation level of X2 dB to the signal received by antenna 34-2, the signal attenuator 46 in phase and magnitude controller 38-N may apply an attenuation level of XN dB to the signal received by antenna 34-N, etc.

Control signals S may control, set, and/or adjust (tune) the gain of the LNA 42, the phase shift of the phase shifter 44, and/or the attenuation level X of the signal attenuator 46 in each phase and magnitude controller 38 over time. The gains of LNAs 42, the phase shifts of phase shifters 44, and/or the attenuation levels X of signal attenuators 46 across phased antenna array 36 may be selected to form a corresponding signal beam B for phased antenna array 36 that is oriented in a selected beam pointing direction 48 (e.g., in the direction of external communications equipment that is transmitting the received signal) and may be adjusted over time to steer or move signal beam B to other beam pointing directions. Phased antenna array 36 may receive the signal from beam pointing direction 48 using signal beam B. A signal splitter/combiner 40 may add the signals received by each antenna 34 together after phase and magnitude controllers 38 have provided the received signals with respective phase and magnitude settings and may provide the added signal to the transceiver or other circuitry in the receive chain.

Signal attenuators 46 may help to tweak the signal level (magnitude or amplitude) of the signals received by each antenna 34 to different desired values that serve to maximize the overall signal-to-noise-and-distortion ratio (SNDR) of the received signals. For example, signal attenuators 46 may use attenuation levels X to perform gain-tapering that provides spatial filtering for phased antenna array 36. The spatial filtering may serve to tweak the shape and/or orientation of signal beam B in a manner that prevents the reception of unwanted jammer signals 50 by phased antenna array 36 (e.g., to prevent the reception of undesirable jammer signals 50 received from directions other than beam pointing direction 48 such as directions 48′). When received by phased antenna array 36, jammer signals 50 can produce undesirable noise and/or distortion in the received signals that limits the SNDR of the received signals and/or that otherwise interferes with proper reception and demodulation of wireless data in the received signals.

Signal attenuators 46 are resistive attenuators that use a set of one or more resistors to attenuate the received signal. Each signal attenuator 46 may receive a signal and may output the signal as an attenuated signal having a magnitude that is attenuated from the magnitude of the received signal by an attenuation level of X dB. In implementations that are described herein as an example, signal attenuators 46 are resistive, differential, pi (π) attenuators that are implemented using a pi network (sometimes also referred to as a pi circuit, pi pad, π network, π circuit, or π pad) disposed on a differential signal path in radio-frequency transmission line paths 32. Signal attenuators 46 may therefore sometimes be referred to herein as pi attenuators 46, resistive pi attenuators 46, pi networks 46, pi pads 46, pi filters 46, pi circuits 46, differential pi attenuators 46, π attenuators 46, resistive π attenuators 46, π networks 46, π pads 46, π circuits 46, π filters, differential π attenuators 46, radio-frequency circuitry 46, or radio-frequency circuit components 46.

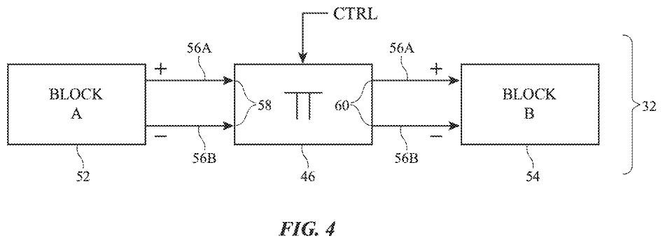

The example of FIG. 3 is illustrative and non-limiting. In general, signal attenuators 46 may be disposed at any desired location (e.g., between any desired circuit blocks) in any desired differential signal path of any desired radio-frequency transmission line path in device 10. FIG. 4 is a generalized circuit diagram showing how a signal attenuator may be disposed on a differential signal path in device 10.

As shown in FIG. 4, radio-frequency transmission line path 32 may include a differential signal path 56. A first circuit block (A) 52 and a second circuit block (B) 54 may be disposed on differential signal path 56. Signal attenuator 46 may be disposed on differential signal path 56 between circuit block 52 and circuit block 54 (e.g., signal attenuator 46 may be coupled or interposed between circuit blocks 52 and 54).

Differential signal path 56 may have a differential pair of signal lines 56A and 56B coupled in parallel between circuit blocks 52 and 54. Signal attenuator 46 may have an input 58 coupled to the output of circuit block 52 over signal lines 56A and 56B. Signal attenuator 46 may have an output 60 coupled to the input of circuit block 54 over signal lines 56A and 56B.

Circuit block 52 may include one or more circuit components arranged in any desired manner on differential signal path 56. For example, circuit block 52 may include an amplifier (e.g., LNA 42 of FIG. 3 when differential signal path 56 forms part of a receive chain, a power amplifier when differential signal path 56 forms part of a transmit chain, etc.), a phase shifter (e.g., phase shifter 44 of FIG. 3), filter circuitry, switching circuitry, antenna tuning circuitry, impedance matching circuitry, mixer circuitry, analog-to-digital converter (ADC) circuitry, digital-to-analog converter (DAC) circuitry, encoder circuitry, decoder circuitry, modulation circuitry, demodulation circuitry, a signal generator, a signal source, a synthesizer, an antenna 34, a radio-frequency connector, a board-to-board connector, a radio-frequency integrated circuit (RFIC), front end circuitry, a radio-frequency front end module, and/or any other desired circuit components in wireless circuitry 24 or elsewhere in device 10.

Similarly, circuit block 54 may include one or more circuit components arranged in any desired manner on differential signal path 56. For example, circuit block 54 may include an amplifier (e.g., LNA 42 of FIG. 3 when differential signal path 56 forms part of a receive chain, a power amplifier when differential signal path 56 forms part of a transmit chain, etc.), a phase shifter (e.g., phase shifter 44 of FIG. 3), filter circuitry, switching circuitry, antenna tuning circuitry, impedance matching circuitry, mixer circuitry, ADC circuitry, DAC circuitry, encoder circuitry, decoder circuitry, modulation circuitry, demodulation circuitry, a signal generator, a signal source, a synthesizer, an antenna 34, a radio-frequency connector, a board-to-board connector, a radio-frequency integrated circuit (RFIC), front end circuitry, a radio-frequency front end module, and/or any other desired circuit components in wireless circuitry 24 or elsewhere in device 10.

Circuit block 52 may transmit a signal (e.g., a radio-frequency signal) over differential signal path 56. Signal attenuator 46 may receive the signal from circuit block 52 over differential signal path 56 and input 58. Input 58 may sometimes also be referred to herein as input port 58. Signal attenuator 46 may apply an attenuation level of X dB to the signal received from circuit block 52 to generate an attenuated signal that is output onto differential signal path 56 via output 60 (e.g., a signal having a magnitude that is X dB lower than the signal received from circuit block 52). Output 60 may sometimes also be referred to herein as output port 60. Circuit block 54 may receive the attenuated signal from signal attenuator 46 over differential signal path 56.

Signal attenuator 46 may receive control signal CTRL (e.g., as a part of a corresponding control signal S as shown in FIGS. 2 and 3). Signal attenuator 46 may include switching circuitry (e.g., one or more switches). Control signal CTRL may adjust the switching circuitry to control the attenuation level X of signal attenuator 46 (e.g., signal attenuator 46 may apply a selected attenuation level X based on control signal CTRL). Control signal CTRL may be used to adjust attenuation level X over time (e.g., to provide optimal spatial filtering and beam forming for the corresponding phased antenna array 36, which may change over time).

In practice, signal attenuator 46 needs to exhibit relatively low phase variation at different attenuation levels X (e.g., signal attenuator 46 needs to output attenuated signals having a relatively constant phase regardless of the attenuation level X applied to the signals). If signal attenuator 46 exhibits excessive phase variation across different attenuation levels X, the spatial filtering provided by the signal attenuator may deteriorate, causing the shape and/or orientation of signal beam B to change such that phased antenna array 36 receives undesirable jammer signals 50 from directions 48′ in addition to the signal of interest to be received from beam pointing direction 48 (FIG. 3). If care is not taken, parasitic capacitances in the switching circuitry of signal attenuator 46 can produce undesirable feed-forward paths that cause the signal attenuator to exhibit excessive phase variation between different attenuation levels X. To mitigate these issues, each signal attenuator 46 may include cross-coupled capacitors that mitigate the parasitic capacitances of the switching circuitry.

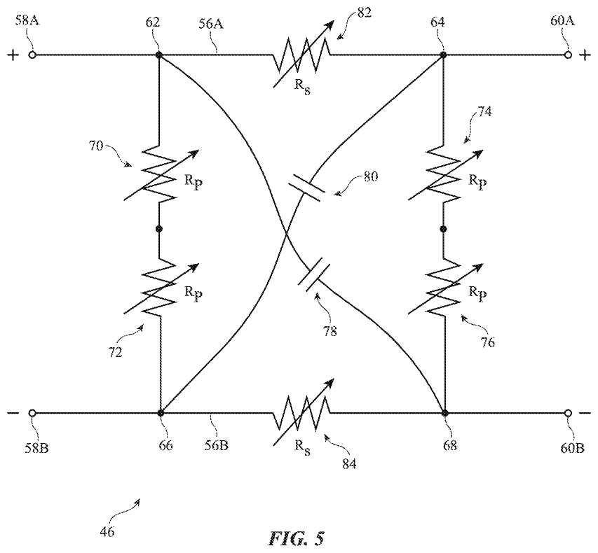

FIG. 5 is a circuit diagram showing how signal attenuator 46 may be provided with cross-coupled capacitors that mitigate these issues. As shown in FIG. 5, the input 58 of signal attenuator 46 may include a first input terminal 58A and a second input terminal 58B. Input terminal 58A may be coupled to the output of circuit block 52 over signal line 56A of differential signal path 56 (FIG. 4). Input terminal 58B may be coupled to the output of circuit block 52 over signal line 56B of differential signal path 56.

The output 60 of signal attenuator 46 may have a first output terminal 60A and a second input terminal 60B. Output terminal 60A may be coupled to the input of circuit block 54 over signal line 56A of differential signal path 56 (FIG. 4). Output terminal 60B may be coupled to the input of circuit block 54 over signal line 56B of differential signal path 56.

Signal attenuator 46 may include a pi network of resistors disposed on and coupled between signal lines 56A and 56B. For example, signal attenuator 46 may include a first series resistor 82 disposed on signal line 56A and coupled in series between input terminal 58A and output terminal 60A. Signal attenuator 46 may include a second series resistor 84 disposed on signal line 56B and coupled in series between input terminal 58B and output terminal 60B. If desired, one of resistors 82 or 84 may be omitted.

Signal attenuator 46 may have a first circuit node 62 on signal line 56A and coupled to input terminal 58A, a second circuit node 64 on signal line 56A and coupled to output terminal 60A, a third circuit node 66 on signal line 56B and coupled to input terminal 58B, and a fourth circuit node 68 on signal line 56B and coupled to output terminal 60B. Resistor 82 may have a first terminal coupled to circuit node 62 and an opposing second terminal coupled to circuit node 64. Resistor 84 may have a first terminal coupled to circuit node 66 and an opposing second terminal coupled to circuit node 68. Circuit nodes 62-68 may sometimes also be referred to herein simply as nodes 62-68.

Signal attenuator 46 may include one or more resistors coupled in parallel between signal lines 56A and 56B on either side of resistors 82 and 84. For example, signal attenuator 46 may include a first resistor 70 and a second resistor 72 coupled in series between circuit nodes 62 and 66. Signal attenuator 46 may include a third resistor 74 and a fourth resistor 76 coupled in series between circuit nodes 64 and 68 (e.g., in parallel with resistors 70 and 72). Resistors 70, 72, 74, and 76 may sometimes also be referred to herein as parallel resistors.

Resistor 70 may have a first terminal coupled to resistor 72 and an opposing second terminal coupled to circuit node 62. Resistor 72 may have a first terminal coupled to circuit node 66 and an opposing second terminal coupled to resistor 70. Resistor 74 may have a first terminal coupled to resistor 76 and an opposing second terminal coupled to circuit node 64. Resistor 76 may have a first terminal coupled to circuit node 68 and an opposing second terminal coupled to resistor 74. If desired, a circuit node between resistors 70 and 72 and/or a circuit node between resistors 74 and 76 may be coupled to a reference potential such as ground. One or more of resistors 70, 72, 74, and 76 may be omitted if desired. Signal attenuator 84 may include additional resistors (not shown), if desired.

Resistors 82 and 84 may exhibit series resistances R_{S} on signal lines 56A and 56B respectively. Resistor 82 and resistor 84 may each exhibit the same resistance R_{S} or may exhibit different resistances R_{S}. Resistors 70-76 may exhibit parallel resistances R_{P} between signal lines 56A and 56B. Resistors 70-76 may each exhibit the same resistance R_{P} or two or more of resistors 70-76 may exhibit different resistances R_{P}.

Resistors 82, 84, 70, 72, 74, and/or 76 may be adjustable resistors. For example, control signal CTRL (FIG. 4) may be provided to resistors 82 and/or 84 to adjust the resistance(s) R_{S} of resistors 82 and/or 84 and/or may be provided to one or more of resistors 70-76 to adjust the resistance(s) R_{P} of resistors 70, 72, 74, and/or 76. The particular value(s) of resistance(s) R_{S} of resistors 82 and/or 84 and/or the particular value(s) of resistance(s) R_{P} of resistors 70, 72, 74, and/or 76 may set the attenuation level X produced by signal attenuator 46. By adjusting the value of one or more of these resistances, control signal CTRL may adjust and set the particular attenuation level X produced by signal attenuator 46 (e.g., the magnitude of the attenuated signals output by signal attenuator 46).

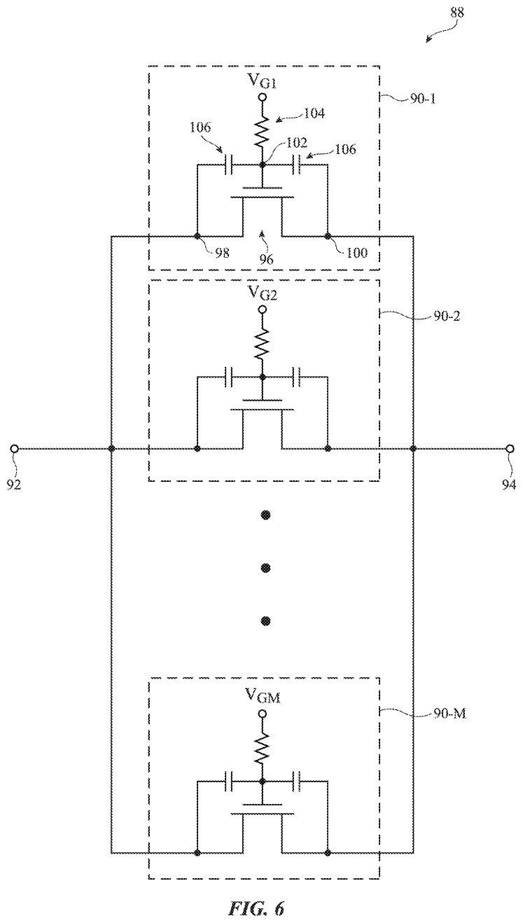

Resistors 82, 84, 70, 72, 74, and/or 76 may include switching circuitry that receives control signal CTRL to set the resistances of resistors 82, 84, 70, 72, 74, and/or 76 and thus attenuation level X. FIG. 6 is a circuit diagram of an adjustable resistor 88 (e.g., any of resistors 82, 84, 70, 72, 74, or 76 of FIG. 5) showing how the adjustable resistor may include switching circuitry for setting the resistance of the adjustable resistor.

As shown in FIG. 6, resistor 88 may include a bank of M switches 90 (e.g., a first switch 90-1, a second switch 90-2, an Mth switch 90-M, etc.) coupled in parallel between a first terminal 92 and a second terminal 94. This example is illustrative and, if desired, one or more of switches 90 may be coupled in series with other switches 90 between terminals 92 and 94 (e.g., switches 90 may be coupled in any desired manner between terminals 92 and 94).

Each switch 90 may include a transistor 96 having a first source/drain terminal 98, a second source/drain terminal 100, and a gate terminal 102. Each switch 90 may include a resistor 104 having a first terminal coupled to gate terminal 102 and having a second terminal that receives a corresponding gate voltage V_{G} (e.g., switch 90-1 may receive gate voltage V_{G1}, switch 90-2 may receive gate voltage V_{G2}, switch 90-M may receive gate voltage V_{GM}, etc.). The control signal CTRL (FIG. 3) provided to signal attenuator 46 may include the different gate voltages V_{G} provided to the switches 90 in each adjustable resistor in the signal attenuator.

Different gate voltages V_{G} may be provided to switches 90 to selectively activate (turn on) or deactivate (turn off) each switch 90. Switches 90 that are turned on exhibit a relatively low (e.g., short circuit) impedance between source/drain terminals 98 and 100 that allows current to pass between terminals 92 and 94 and between terminals 92 and 94 through the corresponding switch 90. Switches 90 that are turned off exhibit a relatively high (e.g., open circuit) impedance between source/drain terminals 98 and 100 to block current from passing between source/drain terminals 98 and 100. The number of switches 90 that are turned on or off may determine the overall resistance of resistor 88. By changing the number of switches 90 that are turned on or off, control signal CTRL may adjust the resistance of resistor 88 at different times. By changing the resistances of different ones of resistors 82, 84, 70, 72, 74, and/or 76, control signal CTRL may adjust the attenuation level X of signal attenuator 46.

In practice, there exist parasitic capacitances 106 between gate terminal 102 and source/drain terminals 98 and 100 of the transistor 96 in each switch 90. Parasitic capacitances 106 may produce a feed-forward current path between source/drain terminals 98 and 100 even when the corresponding switch 90 is turned off. These current paths can cause signal attenuator 46 to introduce different phases to the attenuated signals at different attenuation levels.

To mitigate these issues, as shown in FIG. 5, signal attenuator 84 may include cross-coupled capacitors such as capacitors 80 and 78 coupled between signal lines 56A and 56B and across resistors 82 and 84. Capacitor 78 may be coupled between circuit nodes 62 and 68. For example, capacitor 78 may have a first terminal or capacitor electrode coupled to circuit node 62 (or equivalently the first terminal of resistor 82 or input terminal 58A). Capacitor 78 may have a second terminal or capacitor electrode coupled to circuit node 68 (or equivalently the second terminal of resistor 84 or output terminal 60B). Capacitor 80 may be coupled between circuit nodes 66 and 64. For example, capacitor 80 may have a first terminal or capacitor electrode coupled to circuit node 66 (or equivalently the first terminal of resistor 84 or input terminal 58B). Capacitor 80 may have a second terminal or capacitor electrode coupled to circuit node 64 (or equivalently the second terminal of resistor 82 or output terminal 60A).

The example of FIG. 5 is illustrative and non-limiting. Capacitor 80 may include a single capacitor or may include two or more capacitors coupled in series and/or in parallel between circuit nodes 66 and 64. Capacitor 78 may include a single capacitor or may include two or more capacitors coupled in series and/or in parallel between circuit nodes 62 and 68. If desired, capacitor 78 may be implemented using the parasitic capacitance of one or more switches such as switches 90 (FIG. 6) that are coupled between circuit nodes 62 and 68. If desired, capacitor 80 may be implemented using the parasitic capacitance of one or more switches such as switches 90 (FIG. 6) coupled between circuit nodes 66 and 64.

Capacitors 78 and 80 may each have the same capacitance C_{SW}. Capacitance C_{SW} may be approximately equal to the parasitic capacitances 106 in the switches 90 (FIG. 6) of signal attenuator 46 (e.g., from one or more of the resistors shown in FIG. 5). This may configure capacitors 78 and 80 to mitigate the effect of parasitic capacitances 106, which in turn configures signal attenuator 46 to exhibit minimal phase variation across different attenuation levels X.

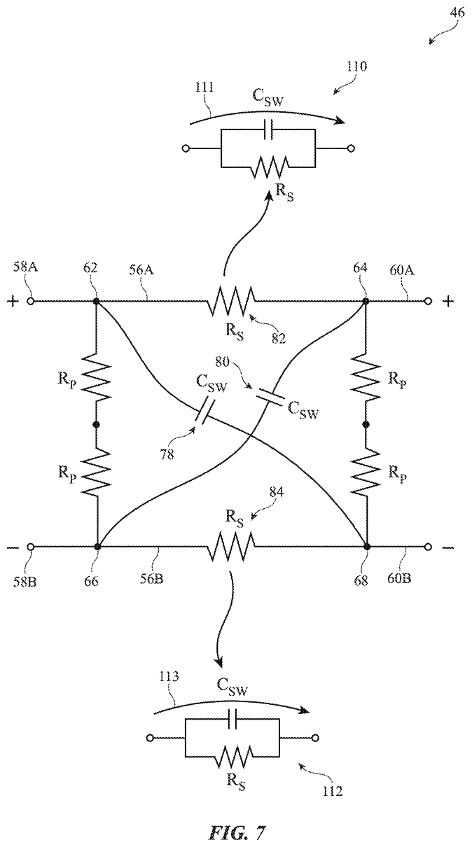

FIGS. 7-9 are equivalent circuit diagrams illustrating how capacitors 78 and 80 may serve to minimize the phase variation of signal attenuator 46 at different attenuation levels X. As shown in FIG. 7, equivalent circuit 110 models the behavior of resistor 82 and equivalent circuit 112 models the behavior of resistor 84. As shown by equivalent circuits 110 and 112, resistors 82 and 80 may each be modeled by a capacitance C_{SW} coupled in parallel with the corresponding resistance R_{S}. Capacitance C_{SW} is given by the parasitic capacitances 106 in the switches 90 (FIG. 6) of the resistors. The capacitance C_{SW} of resistor 82 may form a feed-forward path 111 between the terminals of resistor 82 and thus from circuit node 62 to circuit node 64. Similarly, the capacitance C_{SW} of resistor 84 may form a feed-forward path 113 between the terminals of resistor 84 and thus from circuit node 66 to circuit node 68. In the absence of capacitors 78 and 80, feed-forward paths 111 and 113 may cause the phase of the attenuated signals output by signal attenuator 46 to vary excessively across different attenuation levels X.

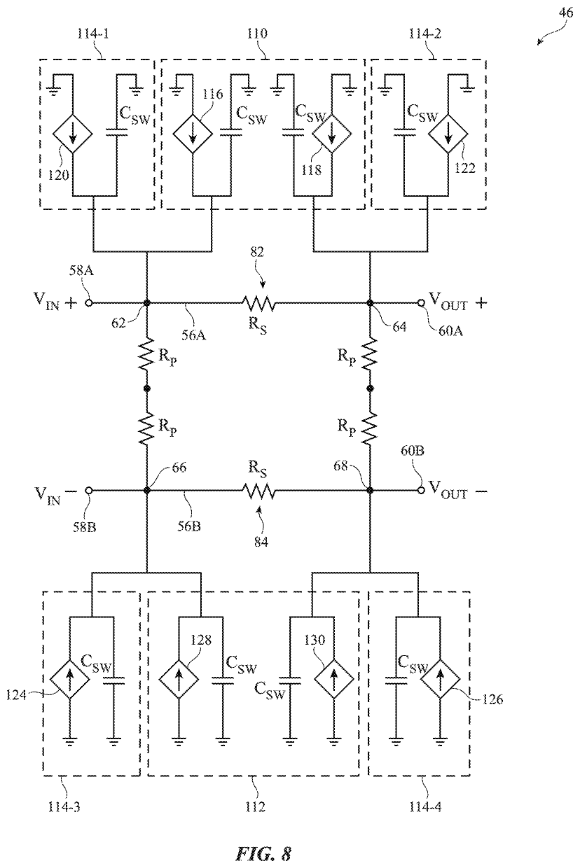

Equivalent circuit 110 for resistor 82 and equivalent circuit 112 for resistor 84 can also be modeled by current sources and capacitances, as shown in FIG. 8. As shown by equivalent circuit 110 of FIG. 8, resistor 82 can be modeled by a first current source 116 and a capacitance C_{SW} coupled in parallel between circuit node 62 and ground and by a second current source 118 and a capacitance C_{SW} coupled in parallel between circuit node 64 and ground. As shown by equivalent circuit 112 of FIG. 8, resistor 84 can be modeled by a third current source 128 and a capacitance C_{SW} coupled in parallel between circuit node 66 and ground and by a fourth current source 126 and a capacitance C_{SW} coupled in parallel between circuit node 68 and ground.

Capacitor 78 is coupled between circuit nodes 68 and 62 (FIGS. 5 and 7) and can be modeled by a first equivalent circuit 114-1 coupled to circuit node 62 and a second equivalent circuit 114-4 coupled to circuit node 68. Capacitor 80 is coupled between circuit nodes 66 and 64 (FIGS. 5 and 7) and can be modeled by a third equivalent circuit 114-3 coupled to circuit node 66 and a fourth equivalent circuit 114-2 coupled to circuit node 64.

Equivalent circuit 114-1 includes a fifth current source 120 and a capacitance C_{SW} coupled between circuit node 62 and ground. Equivalent circuit 114-2 includes a sixth current source 122 and a capacitance C_{SW} coupled between circuit node 64 and ground. Equivalent circuit 114-3 includes a seventh current source 124 and a capacitance C_{SW} coupled between circuit node 66 and ground. Equivalent circuit 114-4 includes an eighth current source 126 and a capacitance C_{SW} coupled between circuit node 68 and ground.

Signal attenuator 46 may receive a signal at input terminals 58A and 58B. The received signal may have magnitude V_{IN+} at input terminal 58A and may have a magnitude V_{IN-} at input terminal 58B. Signal attenuator 46 may attenuate the received signal to output a corresponding attenuated signal (e.g., as attenuated by the selected attenuation level X). The attenuated signal may have a magnitude V_{OUT+} at output terminal 60A and may have a magnitude V_{OUT-} at output terminal 60B.

Current sources 116 and 118 of equivalent circuit 110 can each be modeled by the expression (V_{OUT+})C_{SW}S. Current source 120 of equivalent circuit 114-1 can be modeled by the expression (V_{OUT-})C_{SW}S (e.g., because capacitor 78 couples signal line 56B to circuit node 62 and thus provides current from signal line 56B to circuit node 62). As such, current source 120 cancels out current source 116 from equivalent circuit 110. Similarly, current source 122 of equivalent circuit 114-2 can be modeled by the expression (V_{OUT-})C_{SW}S (e.g., because capacitor 80 couples signal line 56B to circuit node 64 and thus provides current from signal line 56B to circuit node 64). As such, current source 122 cancels out current source 118 from equivalent circuit 110.

At the same time, current sources 128 and 130 of equivalent circuit 112 can each be modeled by the expression (V_{OLT-})C_{SW}S. Current source 124 of equivalent circuit 114-3 can be modeled by the expression (V_{OUT+})C_{SW}S (e.g., because capacitor 80 couples signal line 56A to circuit node 66 and thus provides current from signal line 56A to circuit node 66). As such, current source 124 cancels out current source 128 from equivalent circuit 112. Similarly, current source 126 of equivalent circuit 114-4 can be modeled by the expression (V_{OUT-})C_{SW}S (e.g., because capacitor 78 couples signal line 56A to circuit node 68 and thus provides current from signal line 56A to circuit node 68). As such, current source 126 cancels out current source 130 from equivalent circuit 112.

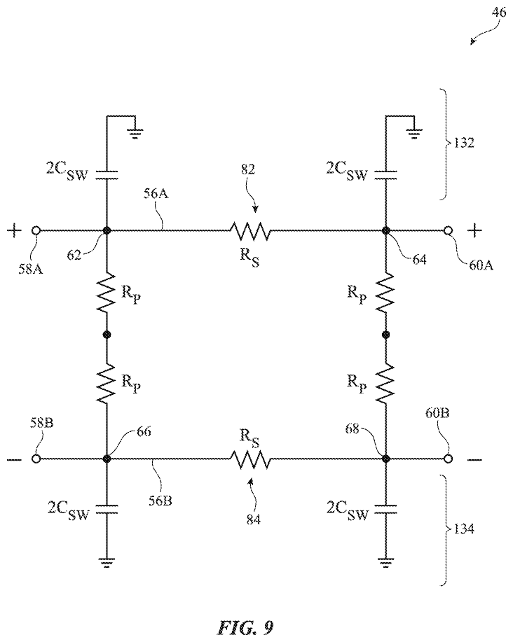

By canceling out the equivalent current sources 116 and 118 from equivalent circuit 110, capacitor 78, capacitor 80, and resistor 82 can then be modeled by equivalent circuit 132 of FIG. 9. As shown by equivalent circuit 132 of FIG. 9, capacitor 78, capacitor 80, and resistor 82 are equivalently modeled by a capacitance of 2C_{SW} coupled between circuit node 62 and ground and by a capacitance of 2C_{SW} coupled between circuit node 62 and ground, without the feed forward path (e.g., equivalent current sources 116 and 118 of FIG. 8) produced by the parasitic capacitances 106 in the switches 90 (FIG. 6) of resistor 82.

Similarly, by canceling out the equivalent current sources 128 and 130 from equivalent circuit 112, capacitor 78, capacitor 80, and resistor 84 can then be modeled by equivalent circuit 134 of FIG. 9. As shown by equivalent circuit 134 of FIG. 9, capacitor 78, capacitor 80, and resistor 84 are equivalently modeled by a capacitance of 2C_{SW} coupled between circuit node 66 and ground and by a capacitance of 2C_{SW} coupled between circuit node 68 and ground, without the feed forward path (e.g., equivalent current sources 128 and 130 of FIG. 8) produced by the parasitic capacitances 106 in the switches 90 (FIG. 6) of resistor 84. The effects of the capacitances 2C_{SW} coupled to circuit nodes 62, 64, 66, and 68 may be canceled out or absorbed by additional components in an impedance matching network of circuit blocks 52 and/or 54 of FIG. 4 if desired.

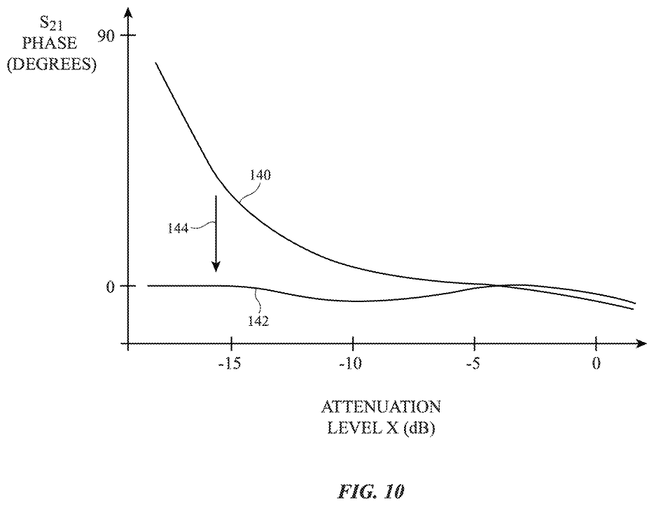

In this way, capacitors 78 and 80 may reverse, neutralize, or mitigate the effects of parasitic capacitances 106 (FIG. 6) on the phase of the attenuated signal produced by signal attenuator 46, such that the attenuated signal has a substantially constant phase at different attenuation levels X (or, put differently, such that signal attenuator 46 exhibits little or no phase variation across attenuation levels X). FIG. 10 is a plot showing how capacitors 78 and 80 may serve to minimize the phase variation across attenuation levels X of signal attenuator 46.

Curve 140 of FIG. 10 plots the phase (angle) of the transmission coefficient S₂₁ of signal attenuator 46 (in degrees) as a function of attenuation level X in the absence of capacitors 78 and 80. Transmission coefficient S₂₁ is a complex scattering parameter that corresponds to the signal transmitted by signal attenuator 46 (e.g., the attenuated signal) relative to the signal received by signal attenuator 46. The phase of S₂₁ therefore corresponds to the phase of the attenuated signal output by signal attenuator 46.

Curve 142 plots the phase of the transmission coefficient S₂₁ of signal attenuator 46 as a function of attenuation level X when capacitors 78 and 80 are coupled between signal lines 56A and 56B. As shown by curve 140, signal attenuator 46 produces a relatively wide range of phases in the attenuated signal across different attenuation levels X due to the feed-forward paths produced by parasitic capacitances 106 in the switches 90 of the adjustable resistor(s) (FIG. 6). As shown by curve 142, signal attenuator 46 produces a relatively narrow range of phases in the attenuated signal across different attenuation levels X. Put differently, as shown by arrow 144, capacitors 78 and 80 may significantly reduce the variation in phase of the attenuated signal as a function of attenuation level X (e.g., due to the current source cancellation illustrated in FIGS. 7-9). The example of FIG. 10 is illustrative and, in practice, curves 140 and 142 may have other shapes.

In this way, signal attenuator 46 may output attenuated signals having a relatively constant phase at different signal attenuation levels X. This may allow signal attenuator 46 to output a consistent and reliable attenuated signal for use by other circuitry in device 10. For example, this may allow signal attenuators 46 to perform satisfactory spatial filtering for phased antenna array 36 (FIG. 3) to allow signals to be conveyed over a signal beam B having a desired beam pointing direction 48 while minimizing noise or distortion produced by unwanted jammer signals incident from other directions.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The methods and operations described above in connection with FIGS. 1-4 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry 18 of FIG. 1, etc.). The processing circuitry may include microprocessors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. An electronic device comprising:
a differential signal path configured to convey a radio-frequency signal, the differential signal path having a first signal line and a second signal line;
a first resistor coupled between a first node on the first signal line and a second node on the second signal line;
a second resistor coupled between a third node on the first signal line and a fourth node on the second signal line;
a third resistor disposed on the first signal line between the first node and the second node;
a first capacitor coupled between the first node and the fourth node; and
a second capacitor coupled between the second node and the third node.

2. The electronic device of claim 1, further comprising a fourth resistor disposed on the second signal line between the second node and the fourth node.

3. The electronic device of claim 2, wherein the third resistor and the fourth resistor are adjustable.

4. The electronic device of claim 2, further comprising:
a fifth resistor coupled in series between the first resistor and the second node; and
a sixth resistor coupled in series between the second resistor and the fourth node.

5. The electronic device of claim 4, wherein a fifth node between the first resistor and the fifth resistor is coupled to a reference potential, and a sixth node between the second resistor and the sixth resistor is coupled to the reference potential.

6. The electronic device of claim 1, wherein the third resistor comprises a set of switches configured to receive gate voltages that configure the third resistor to exhibit a selected resistance.

7. The electronic device of claim 6, wherein the set of switches comprises transistors that exhibit a parasitic capacitance, the first capacitor having a first capacitance equal to the parasitic capacitance, and the second capacitor having a second capacitance equal to the parasitic capacitance.

8. The electronic device of claim 1, further comprising:
a signal attenuator that includes the first resistor, the second resistor, and the third resistor;
a phased antenna array having an antenna coupled to the differential signal path and configured to convey the radio-frequency signal;
an amplifier disposed on the differential signal path; and
a phase shifter disposed on the differential signal path.

9. The electronic device of claim 1, wherein the first resistor, the second resistor, and the third resistor are adjustable.

10. Wireless circuitry comprising:
a phased antenna array having an antenna;
a differential signal path coupled to the antenna and having a first signal line and a second signal line;
a pi network disposed on the differential signal path, wherein the pi network includes a first resistor disposed on the first signal line, the first resistor having a resistance that is adjustable to configure the pi network to attenuate, by different attenuation levels, a radio-frequency signal conveyed using the antenna;
a first capacitor that couples a first terminal of the first resistor to the second signal line; and
a second capacitor that couples a second terminal of the first resistor to the second signal line.

11. The wireless circuitry of claim 10, the pi network comprising:
a second resistor disposed on the second signal path, wherein the second capacitor couples a first terminal of the second resistor to the second terminal of the second resistor, and the first capacitor couples a second terminal of the second resistor to the first terminal of the first resistor.

12. The wireless circuitry of claim 11, wherein the first terminal of the first resistor and the first terminal of the second resistor are coupled to an input of the pi network, the second terminal of the first resistor and the second terminal of the second resistor being coupled to an output of the pi network.

13. The wireless circuitry of claim 12, the pi network further comprising:
a third resistor coupled between the first terminal of the first resistor and the first terminal of the second resistor; and
a fourth resistor coupled between the second terminal of the first resistor and the second terminal of the second resistor.

14. The wireless circuitry of claim 10, wherein the first resistor comprises switching circuitry that exhibits a parasitic capacitance, the first capacitor has a first capacitance equal to the parasitic capacitance, and the second capacitor has a second capacitance equal to the parasitic capacitance.

15. The wireless circuitry of claim 10, further comprising:
an additional differential signal path coupled to an additional antenna in the phased antenna array and having a third signal line and a fourth signal line;
an additional pi network disposed on the additional differential signal path, wherein the additional pi network includes a second resistor disposed on the third signal line, the second resistor having an additional resistance that is adjustable to configure the additional pi network to attenuate, by different attenuation levels, an additional radio-frequency signal conveyed using the additional antenna;
a third capacitor that couples a first terminal of the second resistor to the fourth signal line; and
a fourth capacitor that couples a second terminal of the second resistor to the fourth signal line.

16. The wireless circuitry of claim 10, wherein the first capacitor and the second capacitor are configured to mitigate a feed-forward current path through a switch in the first resistor.

17. Radio-frequency circuitry comprising:
a first signal line coupled between a first input terminal and a first output terminal;
a second signal line coupled between a second input terminal and a second output terminal, wherein the first signal line and the second signal line form a differential pair of signal lines;
a first resistor disposed on the first signal line between the first input terminal and the first output terminal;
a second resistor disposed on the second signal line between the second input terminal and the second output terminal;
a first capacitor that couples the first input terminal to the second output terminal; and
a second capacitor that couples the second input terminal to the first output terminal.

18. The radio-frequency circuitry of claim 17, further comprising:
a third resistor coupled between the first input terminal and the second input terminal; and
a fourth resistor coupled between the first output terminal and the second output terminal.

19. The radio-frequency circuitry of claim 18, wherein one or more of the first resistor, the second resistor, the third resistor, and the fourth resistor are adjustable to configure the radio-frequency circuitry to exhibit a selected attenuation level.

20. The radio-frequency circuitry of claim 17, wherein the first capacitor has a first capacitance and the second capacitor has a second capacitance equal to the first capacitance.
